(19) United States
(12) Patent Application Publication
(10) Pub. No.: US 2026/0179337 A1
(43) Pub. Date: Jun. 25, 2026

(54) GENERATION OF DEPLOYMENT DATA FOR MACHINES BASED ON SIMULATIONS

(71) Applicant: International Business Machines Corporation, Armonk, NY (US)

(72) Inventors: Jennifer M. Hatfield, Portland, OR (US); Jonathan Cottrell, Canandaigua, NY (US); Sarbajit Kumar Rakshit, Kolkata (IN); Carolina Garcia Delgado, Zapopan (MX)

(21) Appl. No.: 18/990,072

(22) Filed: Dec. 20, 2024

(51) Int. Cl. G06T 19/20; G06T 13/20

(52) U.S. Cl. CPC G06T 19/20; G06T 13/20; G06T 2219/2004

(57) ABSTRACT

Generating deployment data for a plurality of physical entities includes generating a virtual environment based on a digital twin model of a physical environment. The physical environment includes the plurality of physical entities. Based on a set of parameters associated with each physical entity of the plurality of physical entities, a plurality of simulations within the virtual environment is performed. The set of parameters includes at least one of one or more mobility parameters associated with each physical entity of the plurality of physical entities, one or more interaction parameters associated with each physical entity of the plurality of physical entities, or one or more spatial parameters associated with each physical entity of the plurality of physical entities. The deployment data for the plurality of physical entities is generated based on the plurality of simulations, and further the deployment data is output.

### BACKGROUND

The disclosure relates generally to the field of control systems, more particularly, to generating deployment data for machines based on simulations.

Machines are widely utilized to perform multiple tasks (such as drilling tasks, cutting tasks, grinding tasks, painting tasks, packaging tasks, mixing tasks, and the like) in various environments (such as factories, construction sites, and the like). A machine is a device or apparatus that executes various operations (such as mechanical operations, electrical operations, hydraulic operations, computational operations, and the like) to perform multiple tasks. The machines include various components (such as pulleys, levers, rotating shafts, screws, and the like) that perform various operations in unison to perform multiple tasks. The machines include, but are not limited to robotic manipulators, forklifts, excavators, loaders, cranes, boring machines, drilling rigs, trucks, and hydraulic breakers. The machines perform multiple tasks faster than manual labor, leading to an increase in operational efficiency and a decrease in operational costs for performing multiple tasks. Additionally, the machines operate in extreme conditions (such as in high temperatures, deep underwater, or in space) where humans cannot safely perform multiple tasks. Moreover, several machines may be scaled up or scaled down to meet the demands of multiple tasks. Hence, there is a need to control the deployment of the machines in various environments to perform multiple tasks optimally while ensuring the safety of the humans working in the vicinity of the machines.

### SUMMARY

According to an embodiment of the disclosure, a computer-implemented method for generating deployment data for physical entities based on simulations is provided. The computer-implemented method includes generating, by a computer, a virtual environment based on a digital twin model of a physical environment. The physical environment includes a plurality of physical entities. The computer-implemented method further includes performing, by the computer, a plurality of simulations within the virtual environment based on a set of parameters associated with each physical entity of the plurality of physical entities. The set of parameters includes at least one of one or more mobility parameters associated with each physical entity of the plurality of physical entities, one or more interaction parameters associated with each physical entity of the plurality of physical entities, or one or more spatial parameters associated with each physical entity of the plurality of physical entities. The computer-implemented method further includes generating, by the computer, deployment data for the plurality of physical entities based on the plurality of simulations. The deployment data includes at least one of position data associated with a position of each physical entity of the plurality of physical entities within the physical environment or temporal data associated with an operation of each physical entity of the plurality of physical entities. The computer-implemented method further includes outputting, by the computer, the deployment data.

According to one or more embodiments of the disclosure, a computer system for generating deployment data for physical entities based on simulations is provided. The computer system includes a processor set, one or more computer-readable storage media, and program instructions stored on the one or more computer-readable storage media. The program instructions are executable by the processor set to cause the processor set to generate a virtual environment based on a digital twin model of an industrial environment. The industrial environment includes a plurality of machines. Each machine of the plurality of machines is associated with one or more industrial processes. The program instructions further cause the processor set to perform a plurality of simulations within the virtual environment based on a set of parameters associated with each machine of the plurality of machines. Each simulation of the plurality of simulations corresponds to execution of at least one of the one or more industrial processes within the virtual environment. Further, the set of parameters includes at least one of one or more mobility parameters associated with each machine of the plurality of machines, one or more interaction parameters associated with each machine of the plurality of machines, or one or more spatial parameters associated with each machine of the plurality of machines. The program instructions further cause the processor set to generate deployment data for the plurality of machines based on the plurality of simulations. The deployment data includes at least one of position data associated with a position of each machine of the plurality of machines within the physical environment, or temporal data associated with an operation of each machine of the plurality of machines. The program instructions further cause the processor set to output the deployment data.

According to one or more embodiments of the disclosure, a computer program product for generation of deployment data for a plurality of physical entities is provided. The computer-program product includes one or more computer-readable storage media. The program instructions stored on the one or more computer-readable storage media to perform operations. The operations include generating a virtual environment based on a digital twin model of a physical environment. The physical environment includes the plurality of physical entities. The operations include performing a plurality of simulations within the virtual environment based on a set of parameters associated with each physical entity of the plurality of physical entities. The set of parameters includes at least one of one or more mobility parameters associated with each physical entity of the plurality of physical entities, one or more interaction parameters associated with each physical entity of the plurality of physical entities, or one or more spatial parameters associated with each physical entity of the plurality of physical entities. The operations include generating the deployment data for the plurality of physical entities based on the plurality of simulations. The deployment data includes at least one of position data associated with a position of each physical entity of the plurality of physical entities within the physical environment or temporal data associated with an operation of each physical entity of the plurality of physical entities. The operations include outputting the deployment data.

Additional technical features and benefits are realized through the techniques of the disclosure. Embodiments and aspects of the disclosure are described in detail herein and are considered a part of the claimed subject matter. For a better understanding, refer to the detailed description and to the drawings.

### BRIEF DESCRIPTION OF THE DRAWINGS

The following description will provide details of preferred embodiments with reference to the following figures wherein:

FIG. 1 is a diagram that illustrates a computing environment 100, in accordance with an embodiment of the disclosure;

FIG. 2 is a diagram that illustrates an environment for generating deployment data for machines based on simulations is provided, in accordance with an embodiment of the disclosure;

FIG. 3 is a diagram that illustrates exemplary operations for generating the deployment data for machines based on the simulations, in accordance with an embodiment of the disclosure;

FIG. 4A is a diagram that illustrates exemplary operations for determination of characteristics data based on an identification of the plurality of physical entities, in accordance with an embodiment of the disclosure;

FIG. 4B is a diagram that illustrates exemplary operations for determination of the one or more control zones for the plurality of physical entities, in accordance with an embodiment of the disclosure;

FIG. 5 is a diagram that illustrates one or more control zones for the plurality of physical entities, in accordance with an embodiment of the disclosure;

FIG. 6 is a diagram that illustrates exemplary operations for generating deployment data for the plurality of machines, in accordance with an embodiment of the disclosure;

FIG. 7 is a diagram depicting training of an Artificial intelligence (AI) model for generation of a digital twin model, in accordance with an embodiment of the disclosure; and

FIG. 8 is a diagram that illustrates a flowchart of a method for generating the deployment data based on the simulations, in accordance with an embodiment of the disclosure.

### DETAILED DESCRIPTION

With the advancement of mechanical technologies, a plurality of machines are widely employed in one or more environments (such as a factory, or a construction site) to perform one or more tasks. Additionally, the plurality of machines may collaborate in the one or more environments to perform the one or more tasks. For example, each machine of the plurality of machines specialized in a specific task of the one or more tasks (such as drilling tasks, cutting tasks, grinding tasks, painting tasks, packaging tasks, mixing tasks, and the like) may execute operations (such as the mechanical operations, electrical operations, hydraulic operations, computational operations, and the like) in a synchronization to achieve a seamless and an efficient workflow. The plurality of machines equipped with diverse end-effectors and functionalities, achieve versatility and precision in the workflow. Such synchronized operations of the plurality of machines lead to increased productivity, faster task completion, and enhanced overall operational efficiency. Additionally, the plurality of machines may operate automatically or manually by users in the one or more environments associated with the one or more tasks. Examples of the users may include, but are not limited to human workers, construction engineers, or assembly operators.

Further, the plurality of machines may be repositioned periodically in the one or more environments to perform the one or more tasks in different positions. For example, the plurality of machines may be repositioned to perform the one or more tasks on an industrial floor, such as regular manufacturing tasks, ad-hoc tasks (such as machine replacement tasks), and material handling tasks. Additionally, the plurality of machines may be repositioned to perform the plurality of tasks in non-designated areas (such as, construction zones, debris fields, and the like).

However, there are challenges associated with the repositioning of the plurality of machines in the one or more environments. For example, each machine of the plurality of machines may have to maintain a safe distance from the users present in the vicinity of the plurality of machines. The safety distance between the plurality of machines and the users ensures the safety of the users present in the vicinity of the plurality of machines. Additionally, each machine of the plurality of machines may have a different operational space that may increase challenges in the determination of positions for the plurality of machines while maintaining the safety distance. For example, moving components of the plurality of machines may cause severe injuries (such as crushed fingers or hands, amputations, burns, or blindness) to the users in the one or more environments. For example, a machine (such as an excavator) includes a moving component to collect debris on the construction site. The moving component may cause injury to a worker performing assigned job duties in the vicinity of the machine. In an additional example, an incorrect repositioning of the plurality of machines in the factory may obstruct a passageway required for the movement of handling equipment (such as trolleys, bins, and the like). Hence, to perform the one or more tasks optimally while ensuring the safety of the users performing assigned duties in the vicinity of the plurality of machines, there is a need for a system that can generate deployment data for the plurality of machines. The deployment data includes position data associated with a position of each physical of the plurality of physical entities within the one or more environments, temporal data associated with the operations of the plurality of machines, or a combination thereof. In an embodiment of the disclosure, the position data includes at least a set of coordinates within the one or more components for the at least one component of each physical entity of the plurality of physical entities. In an embodiment of the disclosure, the temporal data includes at least one or more timestamps for the execution of the operations the plurality of physical entities by the at least one component of the plurality of physical entities. The position data allows for an accurate positioning of the plurality of physical entities while execution of the one or more tasks within the one or more environments. Additionally, the temporal data further allows for a determination of an optimal time for each physical entity of the plurality of physical entities to execute the one or more tasks within the one or more environments.

In an embodiment of the disclosure, the determination of the deployment data for the plurality of physical entities allows for the determination of a safety operation area. This area helps prevent anomalies associated with executing one or more tasks within various environments. As a result, the risk of damage to the components of these physical entities is reduced. Additionally, this leads to an increase in the lifetime of the plurality of physical entities. The anomalies associated with the execution of the one or more tasks within the one or more environments include, but are not limited to, collisions of at least two of the plurality of physical entities or a collision of the plurality of physical entities with the users. Additionally, the maintenance of safety operation areas around the plurality of physical entities facilities safe and quick navigation during an occurrence of the anomalies, leading to a decrease in the likelihood of injuries to the users within the one or more environments.

Further, to ensure a safe working environment (such as in the factory, or the construction site) there may be a need to provide adequate space around the plurality of machines, the determination of the deployment data allows compliance with industrial regulations and safety standards by maintaining the safety operation area around the plurality of machines.

Moreover, the system may iteratively monitor the one or more environments to detect the anomalies associated with the execution of the one or more tasks within the one or more environments. Upon detection of a potential anomaly or an actual anomaly, the system automatically indicates the occurrence of such anomalies to the users by rendering information related to the potential anomaly or the actual anomaly.

According to an embodiment of the disclosure, a computer-implemented method for generating deployment data for physical entities based on simulations is provided. The computer-implemented method includes generating, by a computer, a virtual environment based on a digital twin model of a physical environment. The physical environment includes a plurality of physical entities. The computer-implemented method further includes performing, by the computer, a plurality of simulations within the virtual environment based on a set of parameters associated with each physical entity of the plurality of physical entities. The set of parameters includes at least one of one or more mobility parameters associated with each physical entity of the plurality of physical entities, one or more interaction parameters associated with each physical entity of the plurality of physical entities, or one or more spatial parameters associated with each physical entity of the plurality of physical entities. The computer-implemented method further includes generating, by the computer, deployment data for the plurality of physical entities based on the plurality of simulations. The deployment data includes at least one of position data associated with a position of each physical entity of the plurality of physical entities within the physical environment or temporal data associated with an operation of each physical entity of the plurality of physical entities. The computer-implemented method further includes outputting, by the computer, the deployment data.

In various embodiments of the disclosure, each physical entity of the plurality of physical entities is associated with one or more tasks. Further, each simulation of the plurality of simulations corresponds to execution of at least one of the one or more tasks within the virtual environment.

In various embodiments of the disclosure, to perform the plurality of simulations, the computer-implemented method further includes obtaining, by the computer, characteristics data associated with the physical environment. The computer-implemented method further includes determining, by the computer, one or more control zones associated with each physical entity of the plurality of physical entities based on the set of parameters and the characteristics data. The computer-implemented method further includes executing, by the computer, a feedback loop within the virtual environment based on the execution of the at least one of the one or more tasks. The feedback loop is executed to update at least one of the one or more control zones associated with at least one of the plurality of physical entities.

In various embodiments of the disclosure, to execute the feedback loop, the computer-implemented method further includes updating, by the computer, at least one of the set of parameters associated with the at least one of the plurality of physical entities. The updating is associated with the execution of the feedback loop. The computer-implemented further includes simulating, by the computer, the at least one of the one or more tasks within the virtual environment based on the updating of the at least one of the set of parameters.

In various embodiments of the disclosure, the computer-implemented method further includes each simulation of the plurality of simulations is associated with each iteration of the feedback loop. Further, each simulation of the plurality of simulations corresponds to least one of the execution of the at least one of the one or more tasks associated with the at least one of the plurality of physical entities, or the update of the at least one of the set of parameters associated with the at least one of the plurality of physical entities.

In various embodiments of the disclosure, the computer-implemented method further includes receiving, by the computer, sensor data associated with the physical environment. The computer-implemented method further includes identifying, by the computer, each physical entity of the plurality of physical entities within the physical environment based on the sensor data. The computer-implemented method further includes determining, by the computer, center location data associated with each physical entity of the plurality of physical entities based on entity data associated with each physical entity of the plurality of physical entities. The computer-implemented method further includes determining, by the computer, the characteristics data associated with the physical environment based on the center location. The characteristics data includes task execution data associated with the execution of the at least one of the one or more tasks and distance data associated with the plurality of physical entities.

In various embodiments of the disclosure, the computer-implemented method further includes determining, by the computer, element data associated with one or more movable elements within each physical entity of the plurality of physical entities based on the entity data. The computer-implemented method further includes determining, by the computer, operational range data associated with each movable element of the one or more movable elements based on the center location data, the element data, and the entity data. The computer-implemented method further includes determining, by the computer, the one or more control zones corresponding to each physical entity of the plurality of physical entities based on the operational range data.

In various embodiments of the disclosure, the computer-implemented method further includes determining, by the computer, movement data based on the sensor data. The movement data is associated with one or more users within the physical environment. The computer-implemented method further includes determining, by the computer, an operation area for each user of the one or more users within the physical environment based on the deployment data and the movement data.

In various embodiments of the disclosure, the computer-implemented method further includes determining, by the computer, a distance between the one or more users from the one or more control zones based on the deployment data and the movement data. The computer-implemented method further includes identifying, by the computer, an anomaly based on the distance and the operation area. The computer-implemented method further includes updating, by the computer, the deployment data for the plurality of physical entities based on the anomaly.

In various embodiments of the disclosure, the anomaly is associated with at least one of an overlap between the operation area of at least one of one or more users and the one or more control zones, or the overlap between the one or more control zones.

In various embodiments of the disclosure, the computer-implemented method further includes obtaining, by the computer, visual data associated with the physical environment. The visual data includes object data associated with each physical entity of the plurality of physical entities. The computer-implemented method further includes generating, by the computer, virtual environment data based on the visual data and the digital twin model of the physical environment. The virtual environment data includes a virtual representation of the operation of each physical entity of the plurality of physical entities. The computer-implemented method further includes rendering, by the computer, the virtual environment data on a user device.

In various embodiments of the disclosure, the computer-implemented method further includes updating, by the computer, the virtual environment data based on the anomaly. The computer-implemented method further includes rendering, by the computer, the updated virtual environment data on the user device.

In various embodiments of the disclosure, the one or more spatial parameters associated with each physical entity of the plurality of physical entities indicate at least one of an operational area, a size of the operational area, or a size of the one or more control zones.

In various embodiments of the disclosure, the computer-implemented method further includes training, by the computer, an artificial intelligence (AI) model based on a plurality of training digital twin models associated with a plurality of training physical environments. The computer-implemented method further includes generating, by the computer, the digital twin model of the physical environment based on the trained AI model.

In various embodiments of the disclosure, the one or more mobility parameters at least one of a movement trajectory, a mobility type, one or more speed values, or one or more timestamps associated with the movement trajectory.

In various embodiments of the disclosure, the one or more interaction parameters indicate at least one of a sequence of the operation of each physical entity of the plurality of physical entities, one or more distance values associated with the plurality of physical entities, or one or more timestamps associated with the sequence of the operation of each physical entity of the plurality of physical entities.

In various embodiments of the disclosure, the computer-implemented method further includes controlling, by the computer, the plurality of physical entities in the physical environment based on the deployment data.

In various embodiments of the disclosure, the physical environment corresponds to an industrial environment. The plurality of physical entities corresponds to a plurality of machines operable to execute one or more industrial processes within the industrial environment.

According to one or more embodiments of the disclosure, a computer system for generating deployment data for machines based on simulations is provided. The computer system includes a processor set, one or more computer-readable storage media; and program instructions stored on the one or more computer-readable storage media. The program instructions executable by the processor set to cause the processor set to generate a virtual environment based on a digital twin model of an industrial environment. The industrial environment includes a plurality of machines. Each machine of the plurality of machines is associated with one or more industrial processes. The program instructions further cause the processor set to perform a plurality of simulations within the virtual environment based on a set of parameters associated with each machine of the plurality of machines. Each simulation of the plurality of simulations corresponds to the execution of at least one of the one or more industrial processes within the virtual environment. Further, the set of parameters includes at least one of one or more mobility parameters associated with each machine of the plurality of machines, one or more interaction parameters associated with each machine of the plurality of machines, or one or more spatial parameters associated with each machine of the plurality of machines. The program instructions further cause the processor set to generate deployment data for the plurality of machines based on the plurality of simulations. The deployment data includes at least one of the position data associated with a position of each machine of the plurality of machines within the physical environment or temporal data associated with an operation of each machine of the plurality of machines. The program instructions further cause the processor set to output the deployment data.

According to one or more embodiments of the disclosure, a computer program product for generation of deployment data for a plurality of physical entities is provided. The computer-program product includes one or more computer-readable storage media. The program instructions stored on the one or more computer-readable storage media to perform operations. The operations include generating a virtual environment based on a digital twin model of a physical environment. The physical environment includes the plurality of physical entities. The operations include performing a plurality of simulations within the virtual environment based on a set of parameters associated with each physical entity of the plurality of physical entities. The set of parameters includes at least one of one or more mobility parameters associated with each physical entity of the plurality of physical entities, one or more interaction parameters associated with each physical entity of the plurality of physical entities, or one or more spatial parameters associated with each physical entity of the plurality of physical entities. The operations include generating the deployment data for the plurality of physical entities based on the plurality of simulations. The deployment data includes at least one of the position data associated with a position of each physical entity of the plurality of physical entities within the physical environment or temporal data associated with an operation of each physical entity of the plurality of physical entities. The operations include outputting the deployment data.

Various aspects of the disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated operation, concurrently, or in a manner at least partially overlapping in time.

A computer program product embodiment (“CPP embodiment” or “CPP”) is a term used in the disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer-readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits / lands formed in a major surface of a disc) or any suitable combination of the foregoing. A computer-readable storage medium, as that term is used in the disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation, or garbage collection, but this does not render the storage device as transitory because the data is not transitory while it is stored.

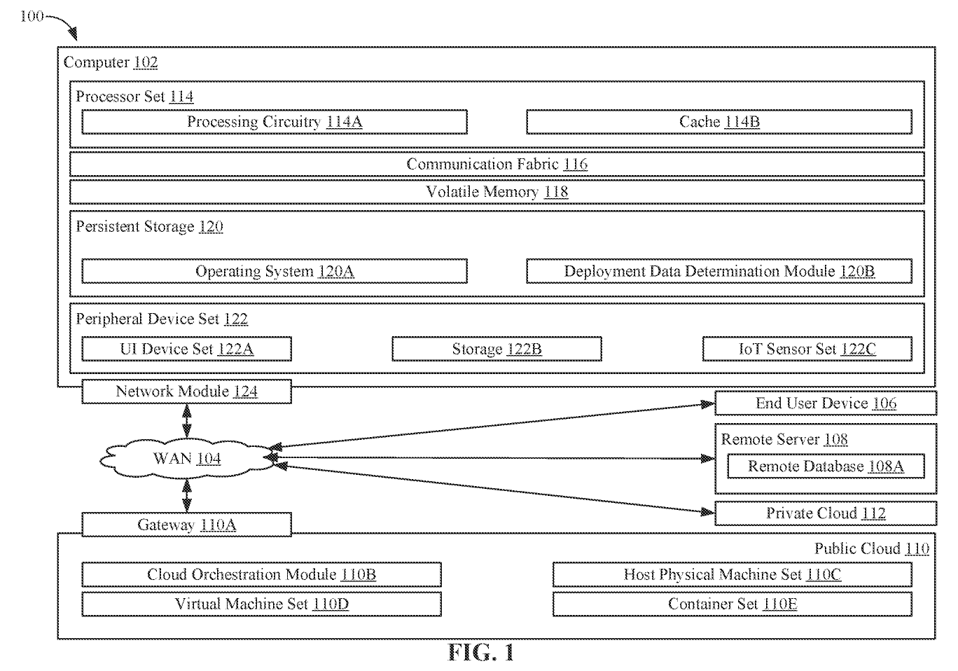

FIG. 1 is a diagram that illustrates a computing environment 100, in accordance with an embodiment of the disclosure. The diagram contains an exemplary environment for the execution of at least one module involved in performing the methods, such as a deployment data determination module 120B associated with generating deployment data for machines based on simulations. In addition to the deployment data determination module 120B, computing environment 100 includes, for example, a computer 102, a wide area network (WAN) 104, an end user device (EUD) 106, a remote server 108, a public cloud 110, and a private cloud 112. In this embodiment of the disclosure, the computer 102 includes a processor set 114 (including a processing circuitry 114A and a cache 114B), a communication fabric 116, a volatile memory 118, a persistent storage 120 (including an operating system 120A and the deployment data determination module 120B, as identified above), a peripheral device set 122 (including a user interface (UI) device set 122A, a storage 122B, and an Internet of Things (IoT) sensor set 122C), and a network module 124. The remote server 108 includes a remote database 108A. The public cloud 110 includes a gateway 110A, a cloud orchestration module 110B, a host physical machine set 110C, a virtual machine set 110D, and a container set 110E.

The computer 102 may take the form of a desktop computer, a laptop computer, a tablet computer, a smartphone, a smartwatch or other wearable computer, a mainframe computer, a quantum computer, or any other form of a computer or a mobile device now known or to be developed in the future that is capable of running a program, accessing a network or querying a database, such as a remote database 108A. As is well understood in the art of computer technology, and depending upon the technology, the performance of a computer-implemented method may be distributed among multiple computers and/or between multiple locations. On the other hand, in this presentation of the computing environment 100, detailed discussion is focused on a single computer, specifically the computer 102, to keep the presentation as simple as possible. The computer 102 may be located in a cloud, even though it is not shown in a cloud in FIG. 1. On the other hand, computer 102 is not required to be in a cloud except to any extent as may be affirmatively indicated.

The processor set 114 includes one, or more, computer processors of any type now known or to be developed in the future. The processing circuitry 114A may be distributed over multiple packages, for example, multiple, coordinated integrated circuit chips. The processing circuitry 114A may implement multiple processor threads and/or multiple processor cores. The cache 114B may be memory that is located in the processor chip package(s) and is typically used for data or code that should be available for rapid access by the threads or cores running on the processor set 114. Cache memories are typically organized into multiple levels depending upon relative proximity to the processing circuitry 114A. Alternatively, some, or all, of the cache 114B for the processor set 114 may be located “off-chip.” In some computing environments, the processor set 114 may be designed for working with qubits and performing quantum computing.

Computer readable program instructions are typically loaded onto the computer 102 to cause a series of operations to be performed by the processor set 114 of the computer 102 and thereby effect a computer-implemented method, such that the instructions thus executed will instantiate the methods specified in flowcharts and/or narrative descriptions of computer-implemented methods included in this document (collectively referred to as “the methods”). These computer-readable program instructions are stored in various types of computer-readable storage media, such as the cache 114B and the other storage media discussed below. The program instructions, and associated data, are accessed by the processor set 114 to control and direct the performance of the methods. In computing environment 100, at least some of the instructions for performing the methods may be stored in the deployment data determination module 120B in persistent storage 120.

The communication fabric 116 is the signal conduction path that allows the various components of computer 102 to communicate with each other. Typically, this fabric is made of switches and electrically conductive paths, such as the switches and electrically conductive paths that make up buses, bridges, physical input/output ports, and the like. Other types of signal communication paths may be used, such as fiber optic communication paths and/or wireless communication paths.

The volatile memory 118 is any type of volatile memory now known or to be developed in the future. Examples include dynamic type random access memory (RAM) or static type RAM. Typically, the volatile memory 118 is characterized by random access, but this is not required unless affirmatively indicated. In the computer 102, the volatile memory 118 is located in a single package and is internal to computer 102, but alternatively or additionally, the volatile memory 118 may be distributed over multiple packages and/or located externally with respect to computer 102.

The persistent storage 120 is any form of non-volatile storage for computers that is now known or to be developed in the future. The non-volatility of this storage means that the stored data is maintained regardless of whether power is being supplied to computer 102 and/or directly to the persistent storage 120. The persistent storage 120 may be a read-only memory (ROM), but typically at least a portion of the persistent storage 120 allows the writing of data, deletion of data, and re-writing of data. Some familiar forms of the persistent storage 120 include magnetic disks and solid-state storage devices. The operating system 120A may take several forms, such as various known proprietary operating systems or open-source Portable Operating System Interface-type operating systems that employ a kernel. The deployment data determination module 120B typically includes at least one module involved in performing the methods.

The peripheral device set 122 includes the set of peripheral devices of computer 102. Data communication connections between the peripheral devices and the other components of computer 102 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments of the disclosure, the UI device set 122A may include components such as a display screen, speaker, microphone, wearable devices (such as goggles and smartwatches), keyboard, mouse, printer, touchpad, game controllers, and haptic devices. The storage 122B is external storage, such as an external hard drive, or insertable storage, such as an SD card. The storage 122B may be persistent and/or volatile. In some embodiments of the disclosure, storage 122B may take the form of a quantum computing storage device for storing data in the form of qubits. In embodiments of the disclosure where computer 102 is required to have a large amount of storage (for example, where computer 102 locally stores and manages a large database) then this storage may be provided by peripheral storage devices designed for storing very large amounts of data, such as a storage area network (SAN) that is shared by multiple, geographically distributed computers. The IoT sensor set 122C is made up of sensors that can be used in Internet of Things applications. For example, one sensor may be a thermometer, and another sensor may be a motion detector.

The network module 124 is the collection of computer software, hardware, and firmware that allows computer 102 to communicate with other computers through WAN 104. The network module 124 may include hardware, such as modems or Wi-Fi signal transceivers, software for packetizing and/or de-packetizing data for communication network transmission, and/or web browser software for communicating data over the internet. In some embodiments of the disclosure, network control functions, and network forwarding functions of the network module 124 are performed on the same physical hardware device. In various embodiments of the disclosure (for example, embodiments that utilize software-defined networking (SDN)), the control functions and the forwarding functions of the network module 124 are performed on physically separate devices, such that the control functions manage several different network hardware devices. Computer-readable program instructions for performing the methods can typically be downloaded to computer 102 from an external computer or external storage device through a network adapter card or network interface included in the network module 124.

The WAN 104 is any wide area network (for example, the internet) capable of communicating computer data over non-local distances by any technology for communicating computer data, now known or to be developed in the future. In some embodiments of the disclosure, the WAN 104 may be replaced and/or supplemented by local area networks (LANs) designed to communicate data between devices located in a local area, such as a Wi-Fi network. The WAN 104 and/or LANs typically include computer hardware such as copper transmission cables, optical transmission fibers, wireless transmission, routers, firewalls, switches, gateway computers, and edge servers.

The EUD 106 is any computer system that is used and controlled by an end user (for example, a customer of an enterprise that operates computer 102) and may take any of the forms discussed above in connection with computer 102. The EUD 106 typically receives helpful and useful data from the operations of computer 102. For example, in a hypothetical case where computer 102 is designed to provide a recommendation to an end user, this recommendation would typically be communicated from the network module 124 of computer 102 through WAN 104 to EUD 106. In this way, the EUD 106 can display, or otherwise present recommendations to an end user. In some embodiments of the disclosure, EUD 106 may be a client device, such as a thin client, heavy client, mainframe computer, desktop computer, and so on.

The remote server 108 is any computer system that serves at least some data and/or functionality to the computer 102. The remote server 108 may be controlled and used by the same entity that operates the computer 102. The remote server 108 represents the machine(s) that collect and store helpful and useful data for use by other computers, such as the computer 102. For example, in a hypothetical case where the computer 102 is designed and programmed to provide a recommendation based on historical data, then this historical data may be provided to the computer 102 from the remote database 108A of the remote server 108.

The public cloud 110 is any computer system available for use by multiple entities that provides on-demand availability of computer system resources and/or other computer capabilities, especially data storage (cloud storage) and computing power, without direct active management by the user. Cloud computing typically leverages the sharing of resources to achieve coherence and economies of scale. The direct and active management of the computing resources of the public cloud 110 is performed by the computer hardware and/or software of the cloud orchestration module 110B. The computing resources provided by the public cloud 110 are typically implemented by virtual computing environments (VCEs) that run on various computers making up the computers of the host physical machine set 110C, which is the universe of physical computers in and/or available to the public cloud 110. The VCEs typically take the form of virtual machines from the virtual machine set 110D and/or containers from the container set 110E. It is understood that these VCEs may be stored as images and may be transferred among and between the various physical machine hosts, either as images or after the instantiation of the VCE. The cloud orchestration module 110B manages the transfer and storage of images, deploys new instantiations of VCEs, and manages active instantiations of VCE deployments. The gateway 110A is the collection of computer software, hardware, and firmware that allows public cloud 110 to communicate through WAN 104.

Some further explanation of virtualized computing environments (VCEs) will now be provided. VCEs can be stored as “images”. A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

The private cloud 112 is similar to public cloud 110, except that the computing resources are only available for use by a single enterprise. While the private cloud 112 is depicted as being in communication with the WAN 104, in various embodiments of the disclosure, a private cloud may be disconnected from the internet entirely and only accessible through a local/private network. A hybrid cloud is a composition of multiple clouds of different types (for example, private, community, or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment of the disclosure, the public cloud 110 and the private cloud 112 are both part of a larger hybrid cloud.

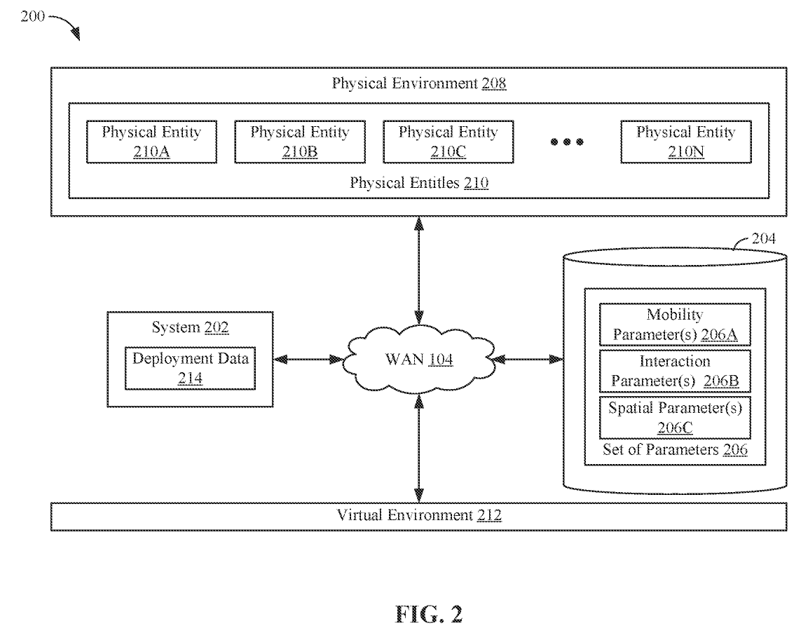

FIG. 2 is a diagram that illustrates an environment for generating deployment data for physical entities based on simulations, in accordance with an embodiment of the disclosure. With reference to FIG. 2, there is shown a network environment 200. The network environment 200 includes a system 202, a database 204 including a set of parameters 206, a physical environment 208 including a plurality of physical entities 210, and a virtual environment 212. The network environment 200 further includes the WAN 104 of FIG. 1. In an embodiment, the physical environment 208 corresponds to a real-world environment that includes a set of physical properties (such as temperature, humidity level, atmospheric pressure, and the like), one or more objects), or any combination thereof. For example, the one or more physical entities may include one or more users, or an infrastructure (such as buildings, floors, roads, and the like). In an embodiment of the disclosure, the physical environment 208 corresponds to an industrial environment (such as a construction site, a factory, and the like). The plurality of physical entities 210 includes a first physical entity 210A, a second physical entity 210B, a third physical entity 210C, up to a Nth physical entity 210N. In an embodiment of the disclosure, each physical entity of the plurality of physical entities 210 is associated with one or more tasks within the physical environment 208. For example, the one or more tasks in a construction environment may be drilling tasks, cutting tasks, grinding tasks, painting tasks, packaging tasks, mixing tasks, and the like. In an embodiment of the disclosure, the plurality of physical entities 210 correspond to a plurality of machines operable to execute the one or more tasks within the industrial environment. In an embodiment of the disclosure, the virtual environment 212 includes a digital representation of the physical environment 208, the plurality of physical entities 210, or a combination thereof.

The system 202 includes suitable logic, circuitry, interfaces, and/or code configured for generating deployment data 214 for the plurality of physical entities 210. The generation of the deployment data 214 allows for accurate repositioning of the plurality of physical entities 210 within the physical environment 208. In an embodiment of the disclosure, the repositioning of the plurality of physical entities 210 corresponds to a change in the position of the plurality of physical entities 210 within the physical environment 208, an orientation of the plurality of physical entities 210 within the physical environment 208, or a combination thereof. In an embodiment of the disclosure, the plurality of machines may be repositioned periodically in the physical environment 208 to perform the one or more tasks in a plurality of positions. For example, the plurality of machines, such as drilling and cutting machines, are repositioned periodically in the physical environment to optimize their effectiveness in road construction. By moving these machines to the plurality of positions as required, the plurality of machines can efficiently perform multiple tasks, such as drilling holes for foundations, cutting materials to size, or paving surfaces—at specific locations along the construction site. This adaptability allows for a more streamlined workflow, ensuring that the necessary operations are completed precisely and promptly, ultimately contributing to the overall efficiency and quality of the road-building process. In an example embodiment, the first physical entity 210A corresponds to an excavator that may be repositioned to perform the drilling tasks in the physical environment 208. In an example embodiment of the disclosure, the excavator may be repositioned from a first position to a second position within the physical environment 208 to perform the drilling tasks. Additionally, the excavator can operate in different environments based on the requirements of the one or more users, necessitating its repositioning after a certain period. Further, the second physical entity 210B corresponds to a surface roller machine that may be repositioned to execute surface flattening tasks. However, there are challenges associated with the repositioning of the plurality of machines in the physical environment 208. For example, each of the excavator and the surface roller machine may have to maintain a safety distance to ensure the safety of the one or more users present in the vicinity of the plurality of machines. Further, the excavator and the surface roller may also maintain a safety distance between each other, as well as with respect to other machines and elements in the physical environment 208. This precaution helps prevent accidents and ensures a safe operational area, promoting efficient workflow while minimizing the risk of collisions or hazards. Further, each machine of the plurality of machines may have a different operational space that may increase challenges in the determination of the plurality of positions for the plurality of machines while maintaining the safety distance from the one or more users. Additionally, contact with operating components of the plurality of machines may cause severe injuries (such as crushed fingers or hands, amputations, burns, or blindness) to the one or more users within the physical environment 208. In order to address the aforementioned challenges, the system 202 is configured to determine the deployment data 214 for each physical entity of the plurality of physical entities.

The database 204 includes suitable logic, circuitry, interfaces, and/or code configured to store a set of parameters 206 associated with each physical entity of the plurality of physical entities 210. The set of parameters 206 includes one or more mobility parameters 206A associated with each physical entity of the plurality of physical entities 210, one or more interaction parameters 206B associated with each physical entity of the plurality of physical entities 210, one or more spatial parameters 206C associated with each physical entity of the plurality of physical entities 210, or any combination thereof. In an embodiment of the disclosure, the one or more mobility parameters 206A indicates a movement trajectory, a mobility type (such as wheeled mobility, rolling mobility, legged mobility, sliding mobility, or hovering mobility), one or more speed values, one or more timestamps associated with the movement trajectory, or any combination thereof. In an embodiment of the disclosure, the one or more speed values are indicative of at least a speed of each physical entity of the plurality of physical entities 210. In an embodiment of the disclosure, the one or more timestamps correspond to specific time instances and indicate the positions of each physical entity within the plurality of physical entities along the movement trajectory during those time periods. In an embodiment of the disclosure, the one or more interaction parameters 206B associated with each physical entity of the plurality of physical entities 210 indicates a sequence of operation of the plurality of physical entities 210, one or more distance values associated with the plurality of physical entities 210, one or more timestamps associated with the sequence of operation, or any combination thereof. In an embodiment of the disclosure, the one or more distance values are indicative of a distance between each physical entity of the plurality of physical entities 210. In various embodiments of the disclosure, the one or more distance values are indicative of a distance between one or more components of the plurality of physical entities 210. In an embodiment of the disclosure, the one or more spatial parameters indicate an operational area, the size of the operational area, the size of one or more control zones, or any combination thereof. In an embodiment of the disclosure, the operational area corresponds to at least one first portion of the physical environment 208 within which the plurality of physical entities 210 operates to execute the one or more tasks. In an embodiment of the disclosure, the at least one portion of the physical environment 208 corresponds to a three-dimensional (3D) space within the physical environment 208. In an embodiment of the disclosure, the one or more control zones correspond to at least one second portion of the physical environment 208 within which the plurality of physical entities 210 may operate to execute the one or more tasks. The execution of the one or more tasks prevents an occurrence of the anomalies within the physical environment 208. In an embodiment of the disclosure, the anomaly corresponds to an overlapping of the one or more control zones within the physical environment 208.

In operation, the system 202 is configured to generate the virtual environment 212 based on a digital twin model of the physical environment 208. In an embodiment of the disclosure, the digital twin model of the physical environment 208 corresponds to a virtual representation of the physical environment 208, the plurality of physical entities 210, or a combination thereof.

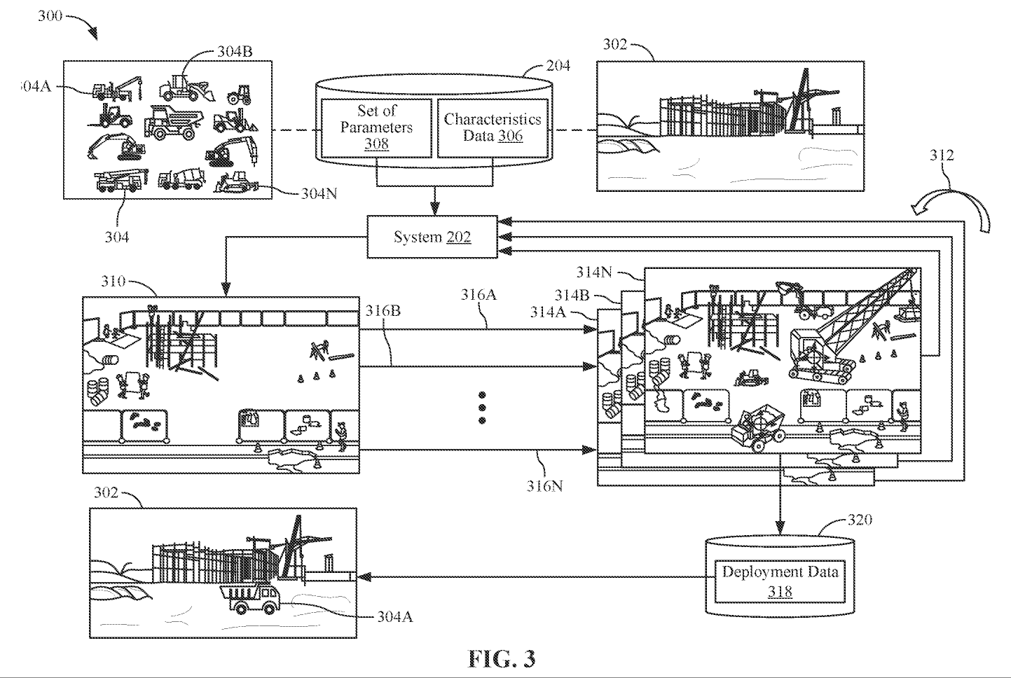

The system 202 is further configured to perform a plurality of simulations within the virtual environment 212 based on the set of parameters 206 associated with each physical entity of the plurality of physical entities 210. In an embodiment of the disclosure, each simulation of the plurality of simulations corresponds to the execution of at least one of the one or more tasks associated with at least one of the plurality of physical entities 210, updating at least one of the set of parameters 206 associated with at least one of the plurality of physical entities 210, or a combination thereof. Details about the plurality of simulations are provided, for example, in FIG. 3.

The system 202 is further configured to generate the deployment data 214 for the plurality of physical entities 210 in the physical environment 208 based on the plurality of simulations. In an embodiment of the disclosure, the deployment data 214 is generated by analyzing the set of parameters associated with the plurality of physical entities 210. The system 202 also considers one or more factors, such as mobility style, collaboration sequence, and the minimum space required around each of the plurality of physical entities 210 while generating the deployment data 214. Further, a series of trial-and-error visual simulations is performed. In the series of trial-and-error visual simulations, the set of parameters (such as, a machine speed, a task duration, and operational pathways) are adjusted to evaluate different scenarios of mobility and activity execution of the plurality of physical entities 210. The series of trial-and-error visual simulations facilitates the identification of certain visual configurations that ensure the necessary safety space around the plurality of physical entities 210 while optimizing the performance of the plurality of physical entities 210. By analyzing the results of the series of trial-and-error visual simulations, the system generates the deployment data/ deployment plan configured for the specific layout and safety requirements of the physical environment 208, ensuring optimal placement and operation of the plurality of physical entities 210. In an embodiment of the disclosure, the system 202 is configured to obtain the set of parameters 206 from the database 204. The deployment data 214 includes position data associated with a position of each physical entity of the plurality of physical entities 210 within the physical environment 208, temporal data associated with an operation of each physical entity of the plurality of physical entities 210, or a combination thereof. In an embodiment of the disclosure, the position data includes at least a set of coordinates within the physical environment 208 for the at least one component of each physical entity of the plurality of physical entities 210. In an embodiment of the disclosure, the temporal data includes at least one or more timestamps for the execution of the operation of each physical entity of the plurality of physical entities 210 by the at least one component of the plurality of physical entities 210.

The position data allows for an accurate positioning of the plurality of physical entities 210 while execution of the one or more tasks within the physical environment 208. Additionally, the temporal data allows for a determination of an optimal time for each physical entity of the plurality of physical entities 210 to execute the one or more tasks within the physical environment 208. The determination of the deployment data 214 for the plurality of physical entities further allows the determination of a safety operation area for the prevention of anomalies associated with the execution of the one or more tasks within the physical environment 208, leading to a decrease in the risk associated with a damage to one or more components of the plurality of physical entities 210. Additionally, the determination of the safety operation area around the plurality of physical entities facilitates safe and quick navigation during an occurrence of the set of anomalies, leading to a decrease in the likelihood of the injuries to the one or more users within the physical environment 208. To maintain a safe working environment, such as in a factory or construction site, it is essential to provide adequate space around the plurality of physical entities 210. The determination of the deployment data 214 facilitates compliance with industrial regulations and safety standards by ensuring that a safety operation area is maintained around the plurality of physical entities 210.

The system 202 is further configured to output the deployment data 214. In an embodiment of the disclosure, the system 202 is configured to output the deployment data 214 on a user interface associated with the system 202. In various embodiments of the disclosure, the system 202 is configured to render an audio output indicative of the deployment data 214. In various embodiments of the disclosure, the system 202 is configured to output the deployment data on a user interface associated with the one or more users. In various embodiments of the disclosure, the system 202 is configured to input the deployment data 214 to each physical entity of the plurality of physical entities 210. In an embodiment of the disclosure, the system 202 is further configured to control the plurality of physical entities 210 based on the deployment data 214. In various embodiment of the disclosure, the system 202 is configured to control the plurality of physical entities to execute the one or more tasks within the physical environment 208.

FIG. 3 is a diagram 300 that illustrates exemplary operations for generating the deployment data for physical entities based on the simulations, in accordance with an embodiment of the disclosure. With reference to FIG. 3, there is shown a physical environment 302. Further, a plurality of physical entities 304 are operable to execute the one or more tasks within the physical environment 302. The plurality of physical entities 304 includes a first physical entity 304A, a second physical entity 304B, and up to an Nth physical entity 304N.

As shown in FIG. 3, the diagram 300 depicts a database 204 storing the characteristics data 306 and a set of parameters 308. Further, the diagram 300 depicts a pictorial representation of the virtual environment 310, a pictorial representation of a feedback loop 312, a pictorial representation of a plurality of simulations 314A, 314B, up to 314N (hereinafter also referred to as plurality of simulations 314), and a pictorial representation of a first iteration 316A, a second iteration 316B, up to an Nth iteration 316N. FIG. 3 also depicts a database 320 storing deployment data 318. In an embodiment of the present disclosure, the system 202 is configured to determine the deployment data 318 for the plurality of physical entities 304. The system 202 is configured to perform the plurality of simulations 314 within the virtual environment 310. Each simulation of the plurality of simulations 314 corresponds to the execution of the at least one of the one or more tasks within a virtual environment 310. Further, the system is configured to generate the deployment data 318 based on the plurality of simulations 314. In an embodiment of the disclosure, to perform the plurality of simulations 314, the system 202 is further configured to obtain the characteristics data 306 associated with the physical environment 302. The characteristics data 306 is indicative of an area associated with the physical environment 302, an operational context associated with the one or more tasks, a criticality level of the one or more tasks, or any combination thereof. In an embodiment of the disclosure, the system 202 is configured to obtain the characteristics data 306 from the database 204. In various embodiments of the disclosure, the system 202 is configured to obtain the characteristics data 306 via a user input from the one or more users. In an embodiment of the disclosure, the operational context corresponds to a type of the one or more tasks. Examples of the type of the one or more tasks include, but are not limited to, a drilling type task, a cutting type task, a grinding type task, a painting type task, a packaging type task, or a mixing type task. In an embodiment of the disclosure, the criticality level is indicative of the likelihood of an occurrence of the anomalies during the execution of the one or more tasks. The system 202 is further configured to determine the one or more control zones associated with each physical entity of the plurality of physical entities 304 based on the set of parameters 308 and the characteristics data 306. The system 202 is further configured to execute the feedback loop 312 within the virtual environment 310 based on the execution of at least one of the one or more tasks associated with at least one of the plurality of physical entities 304. Further, the feedback loop 312 is executed to update at least one of the one or more control zones associated with at least one of the plurality of physical entities 304. In an embodiment of the disclosure, the system 202 is configured to iteratively update at least one of the one or more control zones to minimize the size of the one or more control zones within the virtual environment 310 for performing the at least one of the one or more tasks. In an embodiment of the disclosure, the system 202 is also configured to maximize the size of the one or more control zones within the virtual environment 310 for performing the at least one of the one or more tasks.

In an embodiment of the disclosure, to execute the feedback loop 312, the system 202 is further configured to update at least one of the set of parameters 308 associated with at least one of the plurality of physical entities 304. The updating is associated with the execution of the feedback loop 312. The system 202 is further configured to simulate the at least one of the one or more tasks within the virtual environment based on the updating of the at least one of the set of parameters 308. Specifically, each simulation of the plurality of simulations 314 corresponds to least one of the execution of the at least one of the one or more tasks associated with at least one of the plurality of physical entities 304, or the update of the at least one of the set of parameters 308 associated with the at least one of the plurality of physical entities 304.

In an embodiment of the disclosure, the system 202 is configured to perform the plurality of simulations 314 within the virtual environment 310 based on the set of parameters 308. The set of parameters 308 is associated with each physical entity of the plurality of physical entities 304. In an embodiment of the disclosure, the simulation 314A, the simulation 314B, the simulation 314N may be referred to as the first simulation 314A, the second simulation 314B, and the Nth simulation, respectively. Further, each simulation of the plurality of simulations 314 is associated with each iteration of the feedback loop 312. The feedback loop 312 includes a first iteration 316A, a second iteration, 316B, up to an Nth iteration 316N. In the first iteration 316A, the system 202 is configured to perform the first simulation 314A within the virtual environment based on updating the at least one of the set of parameters 308 associated with execution of at least one of the one or more tasks associated with at least one of the plurality of physical entities 304. In an embodiment of the disclosure, the system 202 is configured to determine a set of execution results based on updating the at least one of the set of parameters 308. Further, each execution result of the set of execution results is associated with a determination of the execution of the at least one task of the one or more tasks associated the one or more control zones.

In an example embodiment of the disclosure, in the first iteration 316A, the system 202 is configured to simulate a movement trajectory of a physical entity, say the first physical entity 304A, of the plurality of physical entities 304 within the virtual environment 310. In an example, a set of simulations from the plurality of simulations may be associated with the first physical entity 304A, specifically a first task of the first physical entity 304A. In this regard, in the first iteration 316A, the first task may be executed based on a set of parameters associated with the first physical entity 304A. For example, the set of parameters may include one or more mobility parameters associated with the first physical entity 304A, one or more interaction parameters associated with the first physical entity 304A, one or more spatial parameters associated with the first physical entity 304A, or a combination thereof. The one or more mobility parameters may indicate a range of motion associated with each component of the first physical entity 304A, the one or more interaction parameters may indicate a manner in which the first physical entity 304A interacts with other physical entities in the physical environment 302, and the one or more spatial parameters may indicate a position and/or an orientation in which the first physical entity 304A is positioned.

Further, to perform the first iteration 316A of the first simulation 314A, characteristics data associated with the physical environment 302 is obtained. The characteristics data may indicate information, such as an area of the physical environment 302, a location associated with the physical environment 302, terrain associated with the physical environment 302, etc. Further, the one or more control zones associated with the first physical entity 304A are determined. In an example, a control zone of the first physical entity 304A may correspond to a maximum operating range of the first physical entity 304A, a second control zone may correspond to an altered operating zone that is restricted, a third control zone may correspond to another altered operating zone that is further restricted, and so forth. Based on the characteristics data of the physical environment 302, the control zones, and the set of parameters of the first physical entity 304A, the feedback loop for the first iteration 316A may be triggered. In particular, the first task may be virtually executed in the first iteration 316A to check whether the first task is efficiently and optimally performed based on the set of parameters of the first physical entity 304A.

In particular, based on the execution of the first task in the first iteration 316A, a determination may be made indicating whether the first physical entity 304A needs to be moved or repositioned in order to perform the first task without any anomaly or risks. For example, if the first iteration 316A of the simulations, i.e., the first simulation 314A, indicates that the first task may not be performed optimally (such as, without risks and/or without anomalies) based on the current set of parameters, these set of parameters may be updated. The output of the first iteration 316A may be provided as feedback for the next iteration. Thereafter, the second iteration 316B or the second simulation 314B may be triggered based on the updated set of parameters. For example, the second iteration 316B may be performed for simulating the first task with the updated set of parameters. With regard to the updated set of parameters, a position or an orientation may be changed, a degree of freedom of components may be changed, a mobility parameter may be changed, a so forth to generate the updated set of parameters. Further, in the second simulation 314B or the second iteration 316B, a determination is made to check whether the first task performed with the updated set of parameters is being performed optimally and without any risks or not. To this end, if the first task is not performed optimally in the second iteration 316B, the set of parameters may be further updated and the third iteration 316C or third simulation may be performed based on the further updated set of parameters. Alternatively, if the first task is performed optimally and without any risks in the second iteration 316B, then next simulation, i.e., third simulation may be performed to simulate a second task of the first physical entity 304A.

Although in the present example described the plurality of simulations with respect to single task of a single physical entity, however this should not be construed as a limitation. In an embodiment, the simulations may be performed such that at least one task to be executed by each of the plurality of physical entities 304 may be simulated together and a set of parameters corresponding to each of the plurality of physical entities 304 may be updated after each iteration or simulation.

To this end, based on the simulations or the iterations of a feedback loop, an optimal setting for execution of tasks in the physical environment 302 is determined. In particular, the setting for the execution of the tasks may indicate a manner in which the plurality of physical entities 304, collectively or independently, may perform tasks. For example, the deployment data for the deployment of the plurality of physical entities 304 in the physical environment 302 may be output to users or to automatically control attributes (such as speed, position, orientation, nature of task, etc.) of the deployment.

In an embodiment of the disclosure, the system 202 is further configured to generate the deployment data 318 for the plurality of physical entities based on the set of parameters associated with the Nth simulation 314N. Further, the system 202 is configured to control the plurality of physical entities 304 in the physical environment 302 based on the deployment data 318. For example, the system 202 is configured to control the first physical entity 304A in the physical environment 302 based on the deployment data 318. The system 202 is further configured to execute the one or more tasks by controlling the first physical entity 304A.

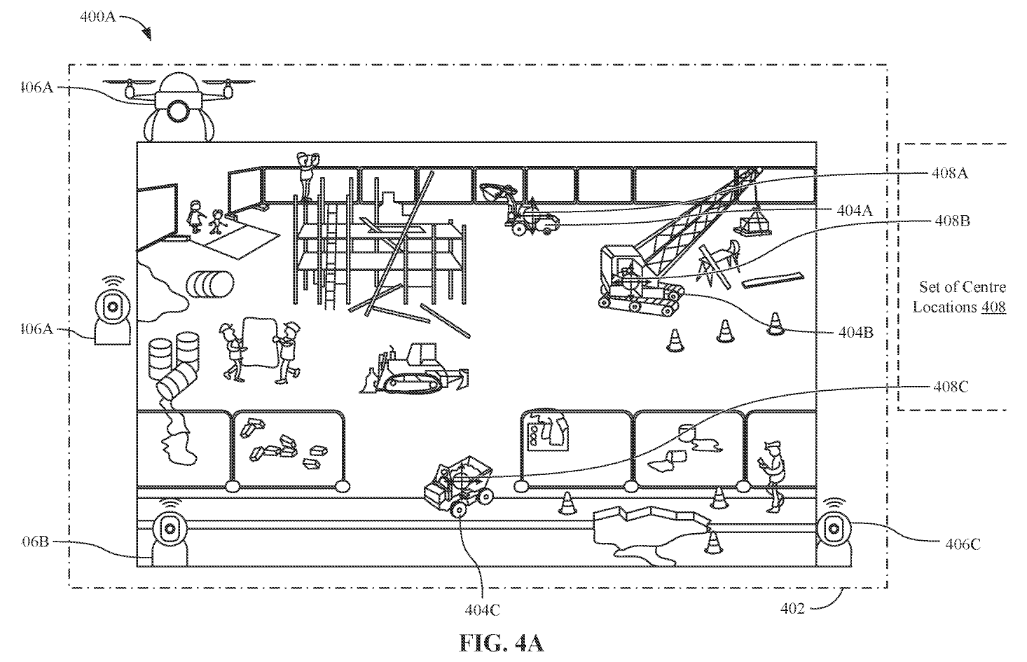

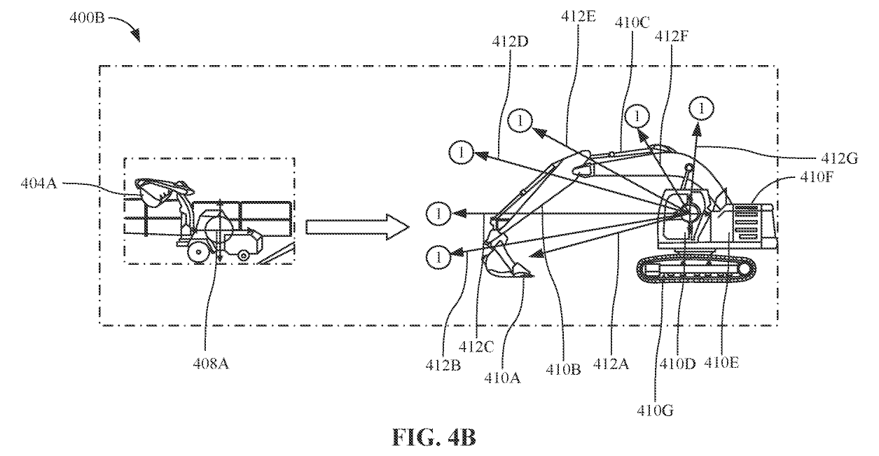

FIG. 4A is a diagram 400A that illustrates exemplary operations for the determination of characteristics data based on an identification of the plurality of physical entities, in accordance with an embodiment of the disclosure. With reference to FIG. 4A, there is shown a physical environment 402 that may include a plurality of physical entities 404A, 404B, 404C (hereinafter also referred to as a plurality of physical entities 404). The plurality of physical entities 404 are operable to execute the one or more tasks in the physical environment 402. In various embodiments of the disclosure, the plurality of physical entities 404 may be referred to as “plurality of machines 404”. In an embodiment of the disclosure, the system 202 is configured to receive sensor data associated with the physical environment 402. The sensor data is indicative of at least a location of each physical entity of the plurality of physical entities 404 within the physical environment 402. In an embodiment of the disclosure, the system 202 is configured to obtain the sensor data from one or more sources 406A, 406B, 406C, and 406D (hereinafter also referred to as one or more sources 406) associated with the physical environment 402. For the sake of explanation, the physical environment 402 including four sources is described. However, the physical environment 402 may include up to an Nth source. In an embodiment of the disclosure, such sensor data may be updated in real-time or near real-time such as within a few seconds, a few minutes, or on an hourly basis, to provide accurate and up-to-date sensor data. Examples of the one or more sources 406 include, but are not limited to, motion sensors, inertia sensors, image capture sensors, proximity sensors, LiDAR sensors, and ultrasonic sensors. Additionally, the one or more sources 406 (such as the source 406D) correspond to unmanned aerial vehicles.

In various embodiments of the disclosure, at least one of the one or more sources 406 are situated in the proximity of the physical environment 402. In various embodiments of the disclosure, at least one of the one or more sources 406 is associated with the plurality of physical entities 404.

The system 202 is further configured to identify each physical entity of the plurality of physical entities 404 within the physical environment 402 based on the sensor data. The system 202 is configured to determine center location data associated with each physical entity of the plurality of identified physical entities (such as the physical entity 404A, the physical entity 404B, and the physical entity 404C). In an embodiment of the disclosure, the system 202 is configured to determine the center location data based on entity data associated with each physical entity of the plurality of physical entities. In an embodiment of the disclosure, the center location data is indicative of at least a set of center locations 408 for each physical entity of the plurality of physical entities 404. The set of center locations 408 includes a center location 408A for the physical entity 404A, a center location 408B for the physical entity 404B, and a center location 408C for the physical entity 404C.

Further, the system 202 is configured to determine the characteristics data associated with the physical environment 402 based on the center location data. The characteristics data includes task execution data associated with execution of at least one of the one or more tasks associated with at least one of the plurality of physical entities 404 and distance data associated with the plurality of physical entities 404. In an embodiment of the disclosure, the task execution data is indicative of a state associated with the execution of the one or more tasks within the physical environment 402. In an embodiment of the disclosure, the distance data is indicative of the distance between each entity of the plurality of physical entity 404 and one or more users within the physical environment 402. In various embodiments of the disclosure, the system 202 is configured to obtain an input from the one or more users. The input is indicative of the type of the one or more tasks, the number of physical entities of the plurality of physical entities 404, a location of the physical environment 402, or any combination thereof. Further, based on the input, the system 202 is configured to determine the characteristics data associated with the physical environment 402.

In an embodiment of the disclosure, the system 202 is configured to determine one or more control zones associated with each physical entity of the plurality of physical entities 404. In an embodiment of the disclosure, the system 202 is configured to determine the one or more control zones based on operational range data. The operational range data is associated with each movable element of the one or more movable elements within each physical entity of the plurality of physical entities 404. In an embodiment of the disclosure, the operational range data is indicative of a distance (such as 2 meters, 4 meters, 8 meters, and the like) of each movable element of the one or more movable elements corresponding to at least one center location of the set of center locations. Accordingly, a diagram is provided to determine operational range data associated with the physical entity 404A with reference to FIG. 4B.

FIG. 4B is a diagram 400B that illustrates exemplary operations for determination of the one or more control zones for the plurality of physical entities, in accordance with an embodiment of the disclosure. With reference to FIG. 4B, there is shown the physical entity 404A having the center location 408A. The physical entity 404A includes one or more movable elements 410A, 410B, 410C, 410D, 410E, 410F, 410G (hereinafter also referred to as one or more movable elements 410). For the sake of explanation, the physical entity 404A including seven movable elements is described. However, the physical entity 404A may include up to a Nth movable element.

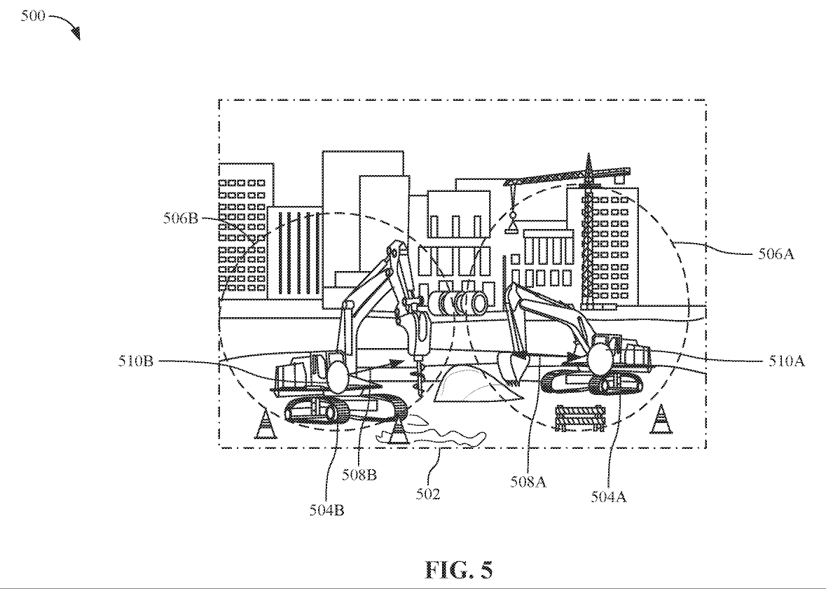

In an embodiment of the disclosure, the system 202 is configured to determine element data associated with the one or more movable elements 410 based on the entity data associated with each physical entity of the plurality of physical entities 404. In an embodiment of the disclosure, the entity data is indicative of an identifier associated with each of the one or more movable elements 410, an operation associated with each of the one or more movable elements 410, a weight of each of the one or more movable elements 410, a position of the one or more movable elements 410 within the physical entity 404A, or any combination thereof. In an embodiment of the disclosure, the element data is indicative of a current location of the one or more movable elements 410. The system 202 is configured to determine operational range data associated with each movable element of the one or more movable elements 410 based on the center location data, the element data, and the entity data. The operational range data is indicative of an operational range of each of the one or more movable elements 410 corresponding to the center location 408A. In an embodiment of the disclosure, the operational range data is indicative of a set of operational ranges for the one or more movable elements 410. By the way of an example and not limitation, the operational range data indicates a set of operational ranges 412A, 412B, 412C, 412D, 412E, 412F, and 412G for the movable element 410A corresponding to the center location 408A. Similarly, the system 202 is configured to determine the operational range data associated with each movable element of the one or more movable elements within each physical entity of the plurality of physical entities based on the center location data, the element data, and the entity data. In various embodiments of the disclosure, the system 202 is configured to determine the one or more control zones associated with each physical entity of the plurality of physical entities 404 based on the operational range data associated with each physical entity of the plurality of physical entities. Accordingly, a diagram is provided with reference to FIG. 5.

FIG. 5 is a diagram 500 that illustrates one or more control zones for the plurality of physical entities, in accordance with an embodiment of the disclosure. With reference to FIG. 5, there is shown a physical environment 502 that includes a plurality of physical entities 504A and 504B (hereinafter also referred to as the plurality of physical entities 504). The plurality of physical entities 504 are operable to execute the one or more tasks in the physical environment 502. In various embodiments of the disclosure, the plurality of physical entities 504 may be referred to as “plurality of machines 504”. In an embodiment of the disclosure, the system 202 is configured to determine a first control zone 506A and a second control zone 506B for the physical entity 504A and the physical entity 504B, respectively. In an embodiment of the disclosure, the system 202 is configured to determine the first control zone 506A and the second control zone 506B based on the operational range data. The operational range data is indicative of a first operational range 508A and a second operational range 508B for the physical entity 504A and the physical entity 504B, respectively. Details about the determination of the operational range data are provided, for example, in FIG. 4B. In an embodiment of the disclosure, the operational range data is indicative of the first operational range 508A and the second operational range 508B corresponding to a center location 510A of the physical entity 504A and a center location 510B of the physical entity 504B, respectively. In an embodiment of the disclosure, the system is configured to determine the center location data to determine center location 510A and the center location 510B.

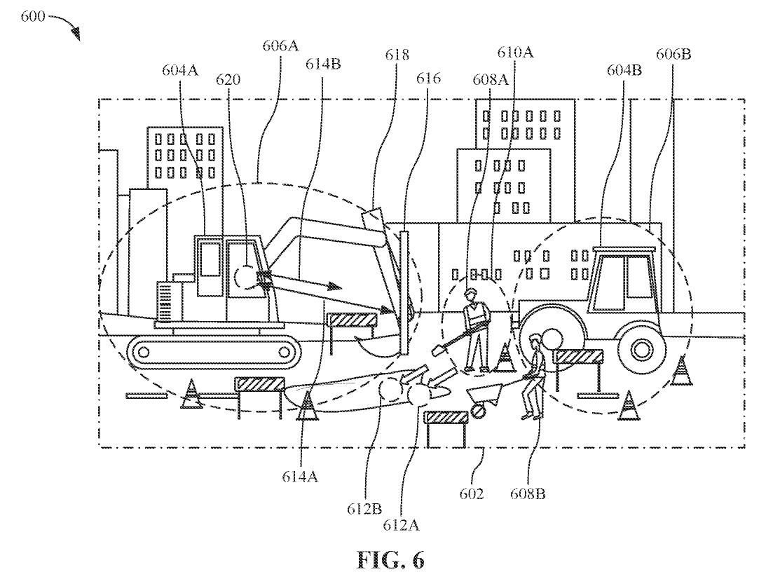

FIG. 6 is a diagram 600 that illustrates exemplary operations for generating deployment data for the plurality of machines, in accordance with an embodiment of the disclosure. With reference to FIG. 6, there is shown a physical environment 602 that may include a plurality of physical entities 604A and 604B (hereinafter also referred to as “plurality of physical entities 604”). Further, one or more control zones 606A and 606B (hereinafter also referred to as “one or more control zones 606”) are associated with the plurality of physical entities 604. Specifically, a control zone 606A and a control zone 606B are associated with the physical entity 604A and the physical entity 604B, respectively. With reference to FIG. 6, one or more users 608A and 608B are shown (hereinafter also referred to as one or more users 608).

In an embodiment of the disclosure, the system 202 is configured to determine movement data associated with a movement of one or more users 608 within the physical environment 602 based on the sensor data. In an embodiment of the disclosure, the movement data is indicative of a movement trajectory of the one or more users 608 in the physical environment 602. In various embodiments of the disclosure, the movement data is indicative of a movement trajectory of one or more raw materials associated with the one or more tasks. The system 202 is further configured to determine an operation area for each user of the one or more users 608 within the physical environment 602 based on the deployment data and the movement data. In an embodiment of the disclosure, the system 202 is configured to determine an operation area 610A for the user 608A. In an embodiment of the disclosure, the system 202 is configured to obtain user data associated with the one or more users 608. In an embodiment of the disclosure, the user data is indicative of at least one of a role associated with the one or more tasks. In an example embodiment of the disclosure, the role corresponds to a human worker, a task supervisor, or a construction engineer. Further, the system 202 is configured to determine the operation area for each user of the one or more users 608 based on the user data, the deployment data, and the movement data.

The system 202 is further configured to determine a distance between the one or more users 608 and the one or more control zones 606 based on deployment data associated with the plurality of physical entities 604 and the movement data. For example, the system 202 is configured to determine a first distance between a first location 612A of the operation area 610A and the control zone 606A at a first time period. In an embodiment of the disclosure, the system 202 is configured to compare the first distance with a safety distance threshold (such as 2 meters, 4 meters, 6 meters, or 8 meters). The system 202 is configured to determine the occurrence of the anomaly based on the comparison of the first distance with the safety distance threshold. In an embodiment of the disclosure, the system 202 is configured to determine an absence of the anomaly based on a determination that the first distance is greater than the safety distance threshold. Further, the system 202 is configured to determine deployment data for the physical entity 604A based on the determination of the absence of the anomaly. The deployment data associated with the physical entity 604A indicates a first operational range 614A for the physical entity 604A. In an embodiment of the disclosure, the first operational range 614A corresponds to a maximum operational range of the physical entity 604A. In an embodiment of the disclosure, the system 202 is further configured to determine a second distance between a second location 612B of the operation area 610A and the control zone 606A at a second time period. The system 202 is configured to identify the anomaly based on the second distance and the operation area 610A. In an embodiment of the disclosure, the system 202 is configured to compare the second distance with the safety distance threshold. The system 202 is configured to determine the occurrence of the anomaly based on the comparison of the first distance with the safety distance threshold. In an embodiment of the disclosure, the system 202 is configured to determine a presence of the anomaly based on a determination that the first distance is less than the safety distance threshold. The system 202 is configured to update the deployment data for the plurality of physical entities 604 based on the anomaly. In an embodiment of the disclosure, the anomaly is associated with at least one of an overlap between the operation area of the one or more users 608 and the one or more control zones 606 associated with each physical entity of the plurality of physical entities 604, an overlap between the one or more control zones associated with at least two of the plurality of physical entities (such as the physical entity 604A and the physical entity 604B), or a combination thereof. In an embodiment of the disclosure, the updated deployment data associated with the physical entity 604A indicates a decrease from a first operational range 614A associated with the first time period to a second operational range 614B associated with the second time period. The first operational range 614A and the second operational range 614B are associated with the physical entity 604A. The decrease in the first operational range 614A ensures the safety of the user 608 within the physical environment 602. The first operational range 614A corresponds to a distance (e.g., 4 meters) from a center location 618 of the physical entity 604A to a first movable element 620. The second operational range 614B corresponds to a distance (e.g., 2 meters) from the center location 618 of the physical entity 604A to the first movable element 620.

In an embodiment of the disclosure, the system 202 is configured to obtain visual data associated with the physical environment 602. The visual data includes object data associated with each physical entity of the plurality of physical entities 604. In an embodiment of the disclosure, the object data indicates a virtual object 616 to indicate the execution of the operation of each physical entity of the plurality of physical entities 604 within the physical environment 602. Further, the virtual object 616 indicates the one or more users 608 to evacuate the physical environment 602. In an embodiment of the disclosure, the system 202 is configured to segment the physical environment 602 for one or more portions.

In an embodiment of the disclosure, the virtual object 616 includes one or a combination of colors to indicate at least the execution of the operation of each physical entity of the plurality of physical entities 604. In an example embodiment of the disclosure, a yellow color indicates aisleways, traffic lanes, paths of edges, work cells, or any combination thereof within the physical environment 602. In an example embodiment of the disclosure, a white color indicates the production of racks, machines, carts, benches, and other equipment within the physical environment 602. In an example embodiment of the disclosure, a red color indicates a defect/scrap area, a red tag area within the physical environment 602. In an example embodiment of the disclosure, the orange color indicates materials, product inspection, and energized equipment within the physical environment 602. In an embodiment of the disclosure, the green color indicates raw materials and first aid-related locations within the physical environment 602. In an example embodiment of the disclosure, the blue color indicates works-in-progress of the one or more tasks within the physical environment 602. In an example embodiment of the disclosure, black color indicates finalized goods within the physical environment 602. In an example embodiment of the disclosure, a combination of the yellow color and the black color indicates a risk to the one or more users within the physical environment 602. In an example embodiment of the disclosure, the white color, and the red color indicate restricted areas to be kept clear for safety reasons (such as emergency access points, electrical panels, and firefighting equipment) within the physical environment 602. In an example embodiment of the disclosure, a combination of the white color and the black color indicates areas to be kept clear for operational purposes (non-safety related) within the physical environment 602.

Further, the system 202 is configured to generate the visual data for each portion of the one or more portions. The system 202 is further configured to generate virtual environment data based on the visual data and the digital twin model of the physical environment 602. The virtual environment data includes a virtual representation of the operation of each physical entity of the plurality of physical entities 604. The system 202 is further configured to render the virtual environment data on a user device. In various embodiments of the disclosure, the system 202 is configured to update the virtual environment data based on the anomaly. Further, the system 202 is configured to render the updated virtual environment data on the user device.

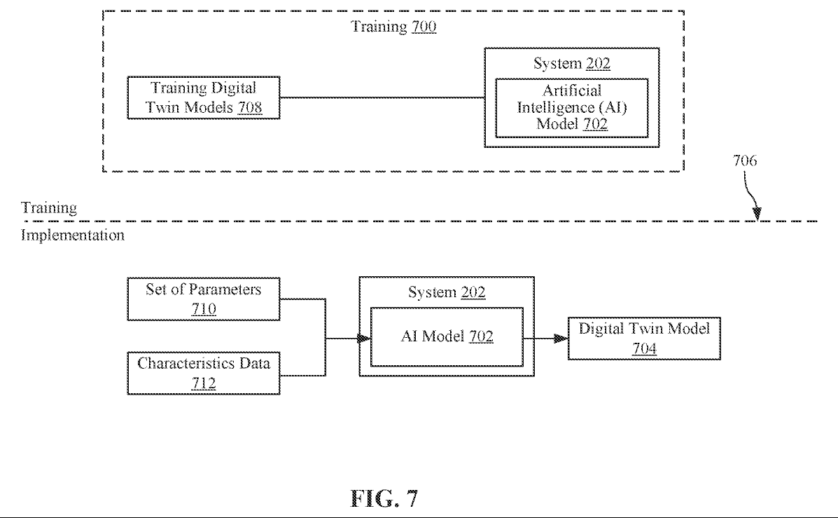

FIG. 7 is a diagram depicting training 700 of AI model 702 for the generation of a digital twin model 704, in accordance with an embodiment of the disclosure. As shown, there is a training portion above line 706 and an implementation portion below line 706. In the training portion above line 706, the system 202 includes the AI model 702 for the generation of the digital twin model 704 associated with a physical environment. In an embodiment of the disclosure, the system 202 is trained based on a plurality of training digital twin models 708. The plurality of training digital twin models 708 are associated with a plurality of training physical environments. Each training digital twin model of the training digital twin model corresponds to a digital representation of a respective training physical environment of the plurality of training physical environments, physical objects (such as the plurality of machines) within the plurality of training physical environments, or processes (such as the one or more operations) associated with the training physical environments. For training 700 of the AI model 702, the system 202 is configured to input the plurality of digital twin models 704 to the AI model 702. Further, based on the plurality of digital twin models 704, the system 202 is configured to train the AI model 702. In an embodiment of the disclosure, the AI model 702 is trained to dynamically adapt to operational changes associated with a state of execution of the one or more operations within the plurality of training physical environments. In various embodiments of the disclosure, the AI model 702 is trained to dynamically adapt to characteristics changes associated with the plurality of training physical environments. Specifically, the AI model 702 is trained to map the physical objects (such as the plurality of machines) into the plurality of training physical environments. In various embodiments of the disclosure, the AI model 702 is trained to simulate, predict, diagnose, and control the state of the physical object within the plurality of training physical environments. In the implementation portion, the system 202 is configured to generate the digital twin model 704 of the physical environment based on the set of parameters 710 and the characteristics data 712. The set of parameters 710 includes one or more mobility parameters associated with each physical entity of the plurality of physical entities, the one or more interaction parameters associated with each physical entity of the plurality of physical entities, one or more spatial parameters associated with each physical entity of the plurality of physical entities, or any combination thereof. Details about the set of parameters 710 are provided, for example, in FIGS. 2 and 3. In an embodiment of the disclosure, the characteristics data 712 is indicative of the area associated with the physical environment, the operational context associated with the one or more tasks, the criticality level of the one or more tasks, or any combination thereof. Details about the characteristics data are provided, for example, in FIG. 3.

In an embodiment of the disclosure, the system 202 is configured to input the set of parameters 710 and the characteristics data 712 into the AI model 702. Additionally, the system 202 generates a digital twin model 704 of the physical environment by applying the AI model 702 to the set of parameters 710 and the characteristics data 712. The digital twin model 704 represents the physical environment, including the plurality of physical entities (such as the plurality of machines), the execution of tasks within the physical environment, or any combination thereof. The AI model 702 is trained to generate a digital representation of the plurality of physical entities and the execution of the one or more tasks within the physical environment based on the one or more mobility parameters associated with each physical entity of the plurality of physical entities, the one or more interaction parameters associated with each physical entity of the plurality of physical entities, and spatial parameters associated with each physical entity of the plurality of physical entities. Furthermore, the AI model 702 is also trained to create the digital representation of the physical environment based on the characteristics data 712. In an embodiment of the disclosure, the AI model 702 is trained to generate a plurality of simulations based on simulating at least one of the one or more tasks within a virtual environment. Further, the system 202 is configured to generate the virtual environment based on the digital twin model 704 of the physical environment. Furthermore, the AI model 702 is trained to iteratively execute the at least one of the one or more tasks based on at least one of updating of the set of parameters 710 or the one or more control zones. In an embodiment of the disclosure, the system 202 is configured to determine a safety space availability score. In an embodiment of the disclosure, the safety availability score is indicative of the size of the one or more control zones. Furthermore, the system 202 is configured to determine a collaboration efficiency score for each simulation of the plurality of simulations. The collaboration efficiency score is indicative of an efficiency associated with the execution of the at least one task of the one or more tasks by a collaboration of the plurality of physical entities. The system 202 is further configured to determine a set of operational scores for each simulation of the plurality of simulations. In an embodiment of the disclosure, the system 202 is configured to determine the set of operational scores based on the safety availability score, the collaboration efficient score, a combination thereof.

Further, each operational score of the set of operational scores is indicative of the operational efficiency of the plurality of physical entities for the execution of the one or more tasks within the virtual environment. Further, the system 202 is configured to identify a simulation from the plurality of simulations based on the set of operational scores. A first operational score of the identified simulation is the highest among the set of operational scores. In an embodiment of the disclosure, the system 202 is configured to determine the deployment data based on the set of parameters 710 corresponding to the identified simulation.

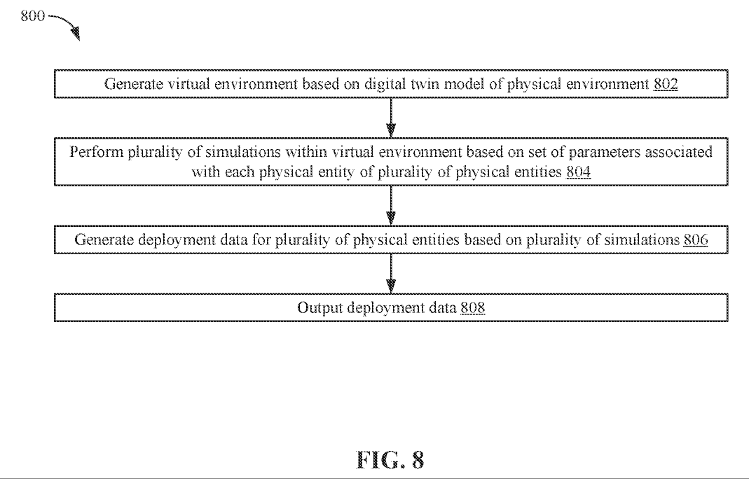

FIG. 8 is a diagram that illustrates a flowchart 800 of a method for generating the deployment data based on the simulations, in accordance with an embodiment of the disclosure. FIG. 8 is explained in conjunction with elements from FIGS. 1-7. The operations of the method depicted by the flowchart 900 may be executed by any computing system, for example, by the computer 102 of FIG. 1 or the system 202 of FIG. 2. The operations of the flowchart 800 may start at 802.

At 802, the virtual environment 310 is generated based on the digital twin model of the physical environment 302. The physical environment 302 includes the plurality of physical entities 304. In an embodiment of the disclosure, the system 202 is further configured to generate the virtual environment 310 based on the digital twin model of the physical environment 302. In various embodiments of the disclosure, the physical environment 302, the plurality of physical entities 304 corresponds to the industrial environment, and the plurality of machines, respectively. Further, the plurality of machines are operable to execute one or more industrial processes (such as the drilling tasks, the cutting tasks, the grinding tasks, the painting tasks, the packaging tasks, the mixing tasks, and the like). In various embodiments of the disclosure, the system, 202 is configured to generate the virtual environment 310 based on a digital twin model of the industrial environment. The industrial environment includes the plurality of machines. Details about the generation of the virtual environment 310 are provided, for example, in FIG. 7.

At 804, the plurality of simulations 314 is performed within the virtual environment 310 based on the set of parameters 308 associated with each physical entity of the plurality of physical entities 304. In an embodiment of the disclosure, the system 202 is configured to perform the plurality of simulations 314 within the virtual environment 310 based on the set of parameters 308 associated with each physical entity of the plurality of physical entities 304. The set of parameters 308 includes at least one of one or more mobility parameters associated with each physical entity of the plurality of physical entities 304, one or more interaction parameters associated with each physical entity of the plurality of physical entities 304, or one or more spatial parameters associated with each physical entity of the plurality of physical entities 304. In various embodiments of the disclosure, the system 202 is configured to perform the plurality of simulations 314 within the virtual environment 310 based on the set of parameters 308 associated with each machine of the plurality of machines. Each simulation of the plurality of simulations 314 corresponds to the execution of at least one of the one or more industrial processes associated with at least one of the plurality of machines within the virtual environment 310. The set of parameters 308 includes at least one of one or more mobility parameters associated with each machine of the plurality of machines, one or more interaction parameters associated with each machine of the plurality of machines, or one or more spatial parameters associated with each machine of the plurality of machines. Details about the generation of the plurality of simulations 314 are provided, for example, in FIG. 3.

At 806, the deployment data 318 is generated for the plurality of physical entities 304 based on the plurality of simulations 314. The deployment data 318 includes at least one of the position data associated with the position of each physical entity of the plurality of physical entities 304 within the physical environment 302 or temporal data associated with an operation of each physical entity of the plurality of physical entities 304. In an embodiment of the disclosure, the system 202 is further configured to generate the deployment data 318 for the plurality of physical entities 304 based on the plurality of simulations 314. In various embodiments of the disclosure, the deployment data 318 is generated for the plurality of machines based on the plurality of simulations 314. The deployment data 318 includes at least one of the position data associated with a position of each machine of the plurality of machines within the physical environment 302 or temporal data associated with an operation of each machine of the plurality of machines. Details about the generation of the deployment data 318 are provided, for example, in FIG. 3.

At 808, the deployment data 318 is output. In an embodiment of the disclosure, the system 202 is configured to output the deployment data 318. Details about the output of the deployment data 318 are provided, for example, in FIG. 2.

While the above steps shown in FIG. 8 are described in a particular sequence, the steps may occur in variations to the sequence in accordance with various embodiments of the present disclosure. Further, details related to various steps of FIG. 8 which are already covered in the description related to FIGS. 1-7 are not discussed again in detail here for the sake of brevity.

While various embodiments of the methods and systems have been described, these embodiments are illustrative and in no way limit the scope of the described methods or systems. Those having skill in the relevant art can effect changes to the form and details of the described methods and systems without departing from the broadest scope of the described methods and systems. Thus, the scope of the methods and systems described herein should not be limited by any of the illustrative embodiments and should be defined in accordance with the accompanying claims and their equivalents.

What is claimed is:

1. A computer-implemented method, comprising:
generating, by a computer, a virtual environment based on a digital twin model of a physical environment, the physical environment comprising a plurality of physical entities;
performing, by the computer, a plurality of simulations within the virtual environment based on a set of parameters associated with each physical entity of the plurality of physical entities, wherein the set of parameters comprises at least one of one or more mobility parameters associated with each physical entity of the plurality of physical entities, one or more interaction parameters associated with each physical entity of the plurality of physical entities, or one or more spatial parameters associated with each physical entity of the plurality of physical entities;
generating, by the computer, deployment data for the plurality of physical entities based on the plurality of simulations, wherein the deployment data comprises at least one of position data associated with a position of each physical entity of the plurality of physical entities within the physical environment or temporal data associated with an operation of each physical entity of the plurality of physical entities; and
outputting, by the computer, the deployment data.

2. The computer-implemented method of claim 1, wherein each physical entity of the plurality of physical entities is associated with one or more tasks, and wherein each simulation of the plurality of simulations corresponds to execution of at least one of the one or more tasks within the virtual environment.

3. The computer-implemented method of claim 2, wherein to perform the plurality of simulations the method further comprises:
obtaining, by the computer, characteristics data associated with the physical environment;
determining, by the computer, one or more control zones associated with each physical entity of the plurality of physical entities based on the set of parameters and the characteristics data; and
executing, by the computer, a feedback loop within the virtual environment based on the execution of the at least one of the one or more tasks, wherein the feedback loop is executed to update at least one of the one or more control zones associated with at least one of the plurality of physical entities.

4. The computer-implemented method of claim 3, wherein the executing of the feedback loop comprises:
updating, by the computer, at least one of the set of parameters associated with the at least one of the plurality of physical entities, wherein the updating is associated with the execution of the feedback loop; and
simulating, by the computer, the at least one of the one or more tasks within the virtual environment based on the updating of the at least one of the set of parameters.

5. The computer-implemented method of claim 4, wherein each simulation of the plurality of simulations is associated with each iteration of the execution of the feedback loop, and wherein each simulation of the plurality of simulations corresponds to at least one of:
the execution of the at least one of the one or more tasks associated with the at least one of the plurality of physical entities, or
the update of the at least one of the set of parameters associated with the at least one of the plurality of physical entities.

6. The computer-implemented method of claim 3, further comprising:
receiving, by the computer, sensor data associated with the physical environment;
identifying, by the computer, each physical entity of the plurality of physical entities within the physical environment based on the sensor data;
determining, by the computer, center location data associated with each physical entity of the plurality of identified physical entities based on entity data associated with each physical entity of the plurality of physical entities; and
determining, by the computer, the characteristics data based on the center location data, wherein the characteristics data comprises task execution data associated with the execution of the at least one of the one or more tasks and distance data associated with the plurality of physical entities.

7. The computer-implemented method of claim 6, further comprising:
determining, by the computer, element data associated with one or more movable elements within each physical entity of the plurality of physical entities based on the entity data;
determining, by the computer, operational range data associated with each movable element of the one or more movable elements based on the center location data, the element data, and the entity data; and
determining, by the computer, the one or more control zones associated with each physical entity of the plurality of physical entities based on the operational range data.

8. The computer-implemented method of claim 6, further comprising:
determining, by the computer, movement data based on the sensor data, wherein the movement data is associated with a movement of one or more users within the physical environment; and
determining, by the computer, an operation area for each user of the one or more users within the physical environment based on the deployment data and the movement data.

9. The computer-implemented method of claim 8, further comprising:
determining, by the computer, a distance between the one or more users and the one or more control zones based on the deployment data and the movement data;
identifying, by the computer, an anomaly based on the distance and the operation area; and
updating, by the computer, the deployment data for the plurality of physical entities based on the anomaly.

10. The computer-implemented method of claim 9, wherein the anomaly is associated with at least one of an overlap between the operation area of at least one of the one or more users and the one or more control zones, or an overlap between the one or more control zones.

11. The computer-implemented method of claim 9, further comprising:
obtaining, by the computer, visual data associated with the physical environment, wherein the visual data comprises object data associated with each physical entity of the plurality of physical entities;
generating, by the computer, virtual environment data based on the visual data and the digital twin model of the physical environment, wherein the virtual environment data comprises a virtual representation of the operation of each physical entity of the plurality of physical entities; and
rendering, by the computer, the virtual environment data on a user device.

12. The computer-implemented method of claim 11, further comprising:
updating, by the computer, the virtual environment data based on the anomaly; and
rendering, by the computer, the updated virtual environment data on the user device.

13. The computer-implemented method of claim 3, wherein the one or more spatial parameters associated with each physical entity of the plurality of physical entities indicates at least one of an operational area, a size of the operational area, or a size of the one or more control zones.

14. The computer-implemented method of claim 1, further comprising:
training, by the computer, an artificial intelligence (AI) model based on a plurality of training digital twin models associated with a plurality of training physical environments; and
generating, by the computer, the digital twin model of the physical environment based on the trained AI model.

15. The computer-implemented method of claim 1, wherein the one or more mobility parameters indicate at least one of a movement trajectory, a mobility type, one or more speed values, or one or more timestamps associated with the movement trajectory.

16. The computer-implemented method of claim 1, wherein the one or more interaction parameters indicate at least one of a sequence of the operation of each physical entity of the plurality of physical entities, one or more distance values associated with the plurality of physical entities, or one or more timestamps associated with the sequence of the operation of each physical entity of the plurality of physical entities.

17. The computer-implemented method of claim 1, further comprising controlling, by the computer, the plurality of physical entities in the physical environment based on the deployment data.

18. The computer-implemented method of claim 1, wherein the physical environment corresponds to an industrial environment, and wherein the plurality of physical entities corresponds to a plurality of machines operable to execute one or more industrial processes within the industrial environment.

19. A computer system, comprising:
a processor set;
one or more computer-readable storage media; and
program instructions stored on the one or more computer-readable storage media, the program instructions executable by the processor set to cause the processor set to:
generate a virtual environment based on a digital twin model of an industrial environment, the industrial environment comprises a plurality of machines, wherein each machine of the plurality of machines is associated with one or more industrial processes;
perform a plurality of simulations within the virtual environment based on a set of parameters associated with each machine of the plurality of machines, each simulation of the plurality of simulations corresponds to execution of at least one of the one or more industrial processes within the virtual environment, wherein the set of parameters comprises at least one of one or more mobility parameters associated with each machine of the plurality of machines, one or more interaction parameters associated with each machine of the plurality of machines, or one or more spatial parameters associated with each machine of the plurality of machines;
generate deployment data for the plurality of machines based on the plurality of simulations, wherein the deployment data comprises at least one of position data associated with a position of each machine of the plurality of machines within the industrial environment or temporal data associated with an operation of each machine of the plurality of machines; and
output the deployment data.

20. A computer program product for generation of deployment data for a plurality of physical entities, the computer program product comprising:
one or more computer-readable storage media; and program instructions stored on the one or more computer-readable storage media to perform operations comprising:
generating a virtual environment based on a digital twin model of a physical environment, the physical environment comprising the plurality of physical entities;
performing a plurality of simulations within the virtual environment based on a set of parameters associated with each physical entity of the plurality of physical entities, wherein the set of parameters comprises at least one of one or more mobility parameters associated with each physical entity of the plurality of physical entities, one or more interaction parameters associated with each physical entity of the plurality of physical entities, or one or more spatial parameters associated with each physical entity of the plurality of physical entities;
generating the deployment data for the plurality of physical entities based on the plurality of simulations, wherein the deployment data comprises at least one of position data associated with a position of each physical entity of the plurality of physical entities within the physical environment or temporal data associated with an operation of each physical entity of the plurality of physical entities; and
outputting the deployment data.
